(19) United States
(12) Patent Application Publication
(10) Pub. No.: US 2024/0260316 A1
(43) Pub. Date: Aug. 1, 2024

(54) DISPLAY APPARATUS

(71) Applicant: LG Display Co., Ltd., Seoul (KR)

(72) Inventors: Chan-Ho LEE, Paju-si (KR); Gyu-Sik WON, Paju-si (KR); Hyun-Je BANG, Paju-si (KR)

(21) Appl. No.: 18/528,672

(22) Filed: Dec. 4, 2023

(30) Foreign Application Priority Data
Jan. 31, 2023 (KR) 10-2023-0012457

(51) Int. Cl. H10K 59/121; H10K 59/131

(52) U.S. Cl. CPC H10K 59/1213; H10K 59/1216; H10K 59/131

(57) ABSTRACT

A display apparatus comprises a substrate including a plurality of sub-pixels, a thin film transistor and a display device disposed in each of the sub-pixels over the substrate, and a plurality of capacitor disposed in parallel on same plane in the sub-pixel.

### CROSS-REFERENCE TO RELATED APPLICATIONS

This application claims priority to and the benefit of Republic of Korea Patent Application No. 10-2023-0012457, filed on Jan. 31, 2023, the disclosure of which is incorporated herein by reference in its entirety.

### BACKGROUND

### 1. Technical Field

This invention relates to a display apparatus capable of repairing a storage capacitor.

### 2. Discussion of the Related Art

Recently, the various display apparatus such as an organic light emitting display apparatus, a micro LED display apparatus, and a mini LED display apparatus are introduced.

In this display apparatus, pixel including and organic light emitting diode, a micro LED, and a mini LED are arranged in a matrix form, and the brightness of the pixel is controlled by the gradation value of image data.

However, if the storage capacitor is defective due to penetration of foreign substances, the repair of the storage capacitor is impossible. Therefore, there was a problem that the display apparatus was defective and even the manufactured display apparatus should be discarded.

### SUMMARY

An object of the invention is to provide a display apparatus capable of repairing a storage capacitor.

The display apparatus according to the invention comprises a substrate including a plurality of sub-pixels, a thin film transistor and a display device disposed in each of the sub-pixels over the substrate, and a plurality of capacitor disposed in parallel on same plane in the sub-pixel.

The thin film transistor includes a semiconductor layer on the substrate, a gate insulating layer on the semiconductor layer, a gate electrode on the gate insulating layer, an interlayer insulating layer on the gate electrode, and a source electrode and a drain electrode on the interlayer insulating layer.

Each of the plurality of capacitor includes a first capacitor electrode and a second capacitor electrode and an insulating layer between the first capacitor electrode and the second capacitor electrode. Each of the plurality of capacitor includes a first capacitor electrode on the gate insulating layer, the interlayer insulting layer, and a second capacitor electrode on the interlayer insulating layer, the first capacitor electrode being overlapped with the second capacitor electrode with the interlayer insulating layer therebetween.

The first capacitor electrode is formed of the same material as the gate electrode and the second capacitor electrode is formed of the same material as the drain electrode. The first capacitor electrode of the plurality of capacitors is connected to a first signal line connected to the gate electrode and the second capacitor electrode of the plurality of capacitors is connected to a second signal line connected to the source electrode.

At least one of a connection of the first capacitor electrode and the first signal line and a connection of the second capacitor electrode and the second signal line may be disconnected in a defective capacitor of the plurality of capacitors.

The plurality of capacitors may be disposed in one side of a region in which the thin film transistor is formed in the sub-pixel. Two capacitors are formed by overlapping one first capacitor electrode and two second capacitor electrodes, and a finger portion is formed in each of the two second capacitor electrodes to interlock with each other.

Further, the plurality of capacitors may be disposed in both sides of the portion in which the thin film transistor is formed in the sub-pixel.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a schematic block diagram of a display apparatus according to an embodiment of the invention.

FIG. 2 is the schematic block diagram of a sub-pixel of the display apparatus according to an embodiment of the invention.

FIG. 3 is the circuit diagram conceptually illustrating the sub-pixel of the display apparatus according to an embodiment of the invention.

FIG. 4 is the cross-sectional view showing the structure of the display apparatus according to an embodiment of the invention in detail.

FIG. 5 is the view showing the structure of a mini LED according to an embodiment of the invention.

FIG. 6A is the view of a plurality of capacitors with vertical structure.

FIG. 6B is the view of a plurality of capacitors with plan structure according to an embodiment of the invention.

FIGS. 7A and 7B are the plan views schematically showing another structure of the display apparatus according to another embodiment of the invention.

### DETAILED DESCRIPTION

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined only by the scope of the appended claims.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is not used, one or more other parts may be located between the two parts.

In describing a temporal relationship, for example, when a temporal predecessor relationship is described as being “after,” “subsequent,” “next to,” “prior to,” or the like, unless “immediately” or “directly” is not used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing the components of the invention, terms such as first, second, A, B, (a), (b), etc. may be used. These terms are only for distinguishing the elements from other elements, and the essence, order, or number of the elements are not limited by the terms. When it is described that a component is “connected” “coupled” or “connected” to another component, the component may be directly connected or connected to the other component, but indirectly without specifically stated It should be understood that other components may be “interposed” between each component that is connected or can be connected.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the invention may include the display apparatus itself such as the LCM, the OLED module, etc., and the application product including the LCM, the OLED module, or the like, or the set apparatus, which is the apparatus for end users.

Hereinafter, the invention will be described in detail with reference to the accompanying drawings.

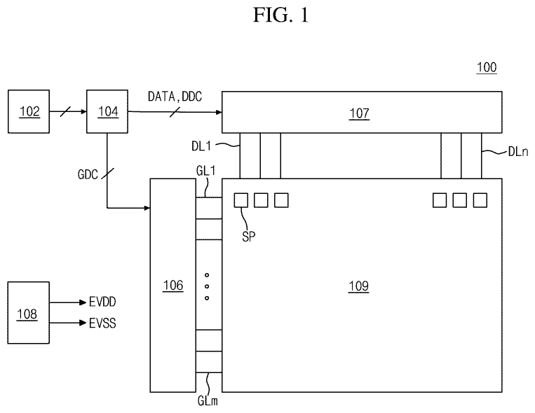

FIG. 1 is the schematic block diagram of the organic light emitting display apparatus according to the invention.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto.

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DLI to DLn. In this case, the data driving unit 107 may be mounted on the upper surface of the display panel 109 in the form of an integrated circuit (IC), but is limited thereto.

The power supplying unit 108 outputs a high potential voltage VDD and a low potential voltage VSS etc. to supply these voltages to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 107, the scan signal from the gage driving unit 106, and the power from the power supplying unit 108.

The display panel includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas. However, embodiments of the present invention are not limited thereto.

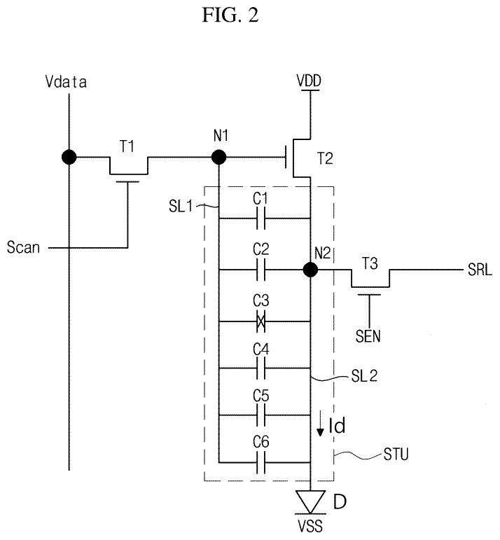

FIG. 2 is a circuit diagram conceptually illustrating a sub-pixel SP of a display apparatus 100 according to the invention.

As shown in FIG. 2, the display apparatus 100 according to the invention includes a display device D, a first transistor T1, a second transistor T2, a third transistor T3, and a storage capacitor unit STU having a plurality of capacitors C1 to C6.

The first transistor T1 may be a switching transistor. The first transistor T1 applies the data voltage Vdata charged in the data line to the first node N1 in response to the scan signal SCAN to turn the second transistor T2. At this time, the gate of the first transistor T1 is connected to the gate line SCAN, the drain is connected to the data line Vdata, and the source is connected to the first node N1.

The second transistor T2 may be a driving transistor. The second transistor T2 controls the current flowing through the light emitting device D according to the gate-source voltage. The gate of the second transistor T2 is connected to the first node N1, the drain is connected to the first power line VDD, and the source is connected to the second node N2.

The third transistor T3 may be a sensing transistor. The third transistor T3 switches the current between the second node N2 and the sensing voltage readout line SRL in response to the sensing signal SEN to output the source voltage of the second N2 to the sensing voltage readout line SRL. The third transistor T3 switches the current between the second node N2 and the sensing voltage readout line SRL in response to the sensing signal SEN to reset the source voltage of the second transistor T2 into the initial voltage. The gate of the third transistor T3 is connected to the sensing line SEN, the drain is connected to the sensing voltage readout line SRL, and the source is connected to the second node N2.

The light emitting device D may be disposed between the second node N2 and the low potential voltage VSS. The first electrode of the light emitting device D is connected to the second node N2, and the second electrode N2 is connected to the low potential voltage VSS. The light emitting device D is for realizing the image, and may be one of various types. For example, the light emitting device D may be a mini LED, a micro LED, or an organic light emitting diode (OLED).

The storage capacitor unit STU is disposed between the first node N1 and the second node N2. The storage capacitor unit STU includes a plurality of capacitors C1 to C6 which are connected in parallel to each other. One ends of the plurality of capacitors C1 to C6 are electrically connected to the first signal line SL1 connected to the first node N1 to receive a data voltage Vdata, and other ends of the plurality of capacitors C1 to C6 are electrically connected to the second signal line SL2 connected to the second node N2 to receive the low potential voltage VSS.

In FIG. 2, six capacitors C1 to C6 are disposed in parallel in the storage capacitor unit STU, but are not limited thereto. For example, two to five capacitors or seven or more capacitors may be disposed in parallel in the storage capacitor unit STU.

The first transistor T1 switches the data voltage path from the data line Vdata in response to the scan signal SCAN input through the gate line. Specifically, the first transistor T1 is turned on by the scan signal SCAN input to the gate through the gate line and then passes the data voltage Vdata input to the drain electrode through the data line to the source electrode, so that the data voltage is supplied to the first node N1 to which the gate electrode of the second transistor T2 is connected.

The second transistor T2 is turned on to correspond to the magnitude of the data voltage input to the gate through the first transistor T1, and then passes the current from the high potential voltage source VDD to the light emitting device D. Therefore, the amount of light emitted from the light emitting element D is controlled according to the amount of current input through the second transistor T2.

As described above, in the invention, since the storage capacitor unit STU disposed between the first node N1 and the second node N2 includes a plurality of capacitors C1 to C6 connected in parallel, the defect can be repaired by removing the corresponding one of the plurality of capacitors C1 to C6 when the capacitor is defective. For example, when the third capacitor C3 is defective, the defect can be solved by cutting the third capacitor C3 with a laser or the like.

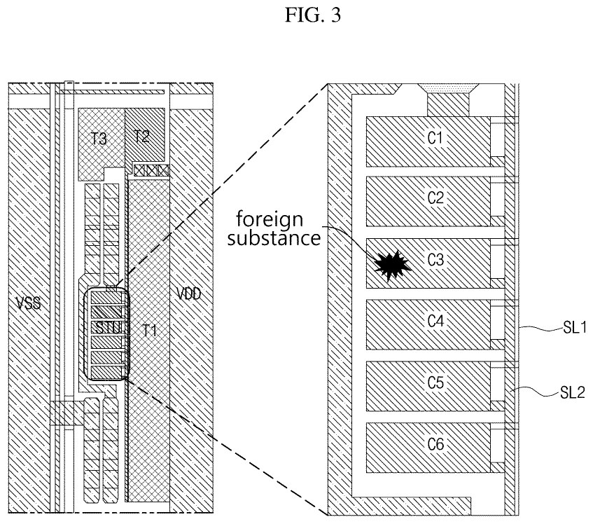

FIG. 3 is a plan view schematically showing the actual structure of the sub-pixel SP of the display apparatus 100 according to the invention.

As shown in FIG. 3, the first power supply line VDD and the second power supply line VSS are disposed in the vertical direction (y-direction) on both sides of the sub-pixels SP. The first transistor T1, the second transistor T2, the third transistor T3, and the storage capacitor unit STU are disposed between the first power supply line VDD and the second power supply line VSS.

The second transistor T2 is disposed on the upper right side of the sub-pixel SP and connected to the gate line and the data line (not shown clearly in FIG. 3), and the third transistor T3 is disposed on the upper left side and connected to the first power supply line VDD and the reference voltage line (not shown clearly in FIG. 3). The storage capacitor unit STU and the display device D are disposed between the first transistor T1 and the second power supply line VSS.

The light emitting device D may be the mini LED, the micro LED, or the organic light emitting device.

The storage capacitor unit STU includes a plurality of capacitors C1 to C6 connected in parallel. The plurality of capacitors C1 to C6 are disposed along the first power supply line VDD and the second power supply line VSS in the central region of the sub-pixel SP. That is, the plurality of capacitors C1 to C6 are connected and disposed in parallel on a plane within the sub-pixel SP.

Although described in more detail later, each of the plurality of capacitors C1 to C6 may be formed of a pair of electrodes facing each other and an insulating layer disposed therebetween. At this time, each electrode is connected to the signal lines SL1 and SL2, and voltages of different levels, for example, the gate voltage corresponding to the scan signal and the data voltage are applied to form storage capacitances in the respective capacitors C1 to C6.

When one of the plurality of capacitors C1 to C6 is defective, for example, when a pair of electrodes is short-circuited due to a foreign substance penetrating the third capacitor C3, the connection between at least one electrode of the two electrodes of the third capacitor C3 and the signal lines SL1 and SL2 is cut by a cutting means such as a laser to remove the third capacitor C3, and the remaining capacitors C1, C2, C4, C5, and C6 can be used to maintain light emission.

As described above, in the invention, since the plurality of capacitors C1 to C6 are disposed in parallel on the same plane in the sub-pixel, when some capacitors are defective, the defective capacitors can be removed. As a result, since the storage capacitor unit STU can be repaired, defects in the display apparatus 100 can be prevented.

Hereinafter, the structure of the display apparatus 100 according to the invention will be described in more detail with reference to the accompanying drawings.

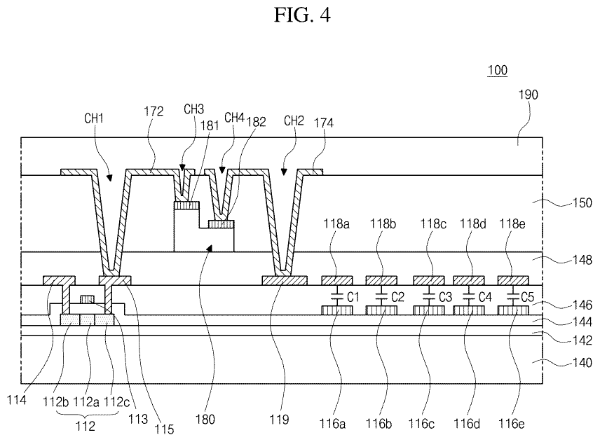

FIG. 4 is the cross-sectional view showing the structure of the display apparatus 100 according to the invention in detail. The invention can be applied to various display apparatus. For example, the invention can be applied to various display apparatuses such as the mini LED display apparatus, the micro LED display apparatus, the organic light emitting display apparatus, and the like, but for convenience of explanation, the mini LED display apparatus will be described as an example in the drawings.

As shown in FIG. 4, a first buffer layer 142 is formed on a substrate 140.

The substrate 140 may be made of a hard transparent material such as glass or a flexible material such as plastic. Further, the substrate 140 may be made of metal.

For example, the plastic material may include a polyimide, a polymethylmethacrylate, a polyethylene terephthalate, a Polyethersulfone, and a Polycarbonate, but is not limited thereto.

When the substrate 140 is made of polyimide, the substrate 140 may be made of a plurality of polyimide layers, and an inorganic layer may be further disposed between the polyimide layers, but is not limited thereto.

The buffer layer 142 may be formed in the entire area of the substrate 140 to enhance adhering force between the substrate 140 and the layers thereon. Further, the buffer layer 142 may block various types of defects, such as alkali components flowing out from the substrate 140. Further, the buffer layer 142 may delay diffusion of moisture or oxygen penetrating into the substrate 140.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. The buffer layer 142 may be omitted based on the type and material of the substrate 140, the structure and type of the thin film transistor, and the like.

A thin film transistor is disposed over the buffer layer 142. For convenience of description, only the driving thin film transistor among various thin film transistors that may be disposed in the R,G,B sub-pixels is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor includes a semiconductor pattern 112 on the buffer layer 142, a gate electrode 113, a source electrode 114, and a drain electrode 115.

The semiconductor pattern 112 may be made of a polycrystalline semiconductor. For example, the polycrystalline semiconductor may be made of low temperature polysilicon (LTPS) having high mobility, but is not limited thereto.

The semiconductor pattern 112 may be made of an oxide semiconductor. For example, semiconductor pattern 112 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at both sides of the channel region 112a.

The gate insulating layer 144 may be formed in the display area AA and the non-display area NA or formed only in the display area AA. The gate insulating layer 144 may be comprised of a single layer or multiple layers made of an inorganic material such as SiOx or SiNx, but is not limited thereto.

The interlayer insulating layer 146 may be formed of the single layer or the multiple layers made of the inorganic material such as SiOx or SiNx, but is not limited thereto.

The source electrode 114 and the drain electrode 115 are formed of the single layer or multiple layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 114 and the drain electrode 115 may be respectively contacted to the source region 112b and the drain region 112c of the semiconductor through contact holes formed in the gate insulating layer 144 and the interlayer insulating layer 146.

Not shown in figure, a bottom shield metal layer may be disposed on the substrate 140 under the semiconductor pattern 112. The bottom shield metal layer minimizes a backchannel phenomenon caused by charges trapped in the substrate 140 to prevent afterimages or deterioration of transistor performance. The bottom shield metal layer may be comprised of a single layer or the multiple layers made of titanium (Ti), molybdenum (Mo), or an alloy thereof, but is not limited thereto.

The drain electrode 115 of the thin film transistor serves as a first electrode for applying a signal to the mini LED. A second electrode 119 for applying the signal to the mini LED is disposed on the gate insulating layer 144. The second electrode 119 may be formed of the single layer or the multiple layers made of any one of molybdenum (Mo), aluminum (Al), chromium (Cr), gold (Au), titanium (Ti), nickel (Ni), neodymium (Nd), copper (Cu), or an alloy thereof, but is not limited thereto. The second electrode 119 is simultaneously formed by the same process as the gate electrode 113, but is not limited thereto.

The plurality of first capacitor electrodes 116a to 116e are spaced apart from each other by the predetermined distance on the gate insulating layer 144. Although not shown in the figure, the plurality of first capacitor electrodes 116a to 116e are connected in parallel.

The first capacitor electrodes 116a to 116e may be formed of a single layer or multiple layers made of at least one of molybdenum (Mo), aluminum (Al), chromium (Cr), gold (Au), titanium (Ti), nickel (Ni), neodymium (Nd), copper (Cu), or alloys thereof, but are not limited thereto. The first capacitor electrodes 116a to 116e may be simultaneously formed by the same process as the gate electrode 113, but are not limited thereto.

The plurality of second capacitor electrodes 118a to 118e are spaced apart from each other by the predetermined distance on the interlayer insulating layer 146. Although not shown in the figure, the second capacitor electrodes 118a to 118e are connected in parallel.

The second capacitor electrodes 118a to 118e may be formed of the single layer or the multi layers made of at least one of molybdenum (Mo), aluminum (Al), chromium (Cr), gold (Au), titanium (Ti), nickel (Ni), neodymium (Nd), copper (Cu), or alloys thereof, but are not limited thereto. The second capacitor electrodes 118a to 118e may be simultaneously formed by the same process as the source electrode 114 and the drain electrode 115, but are not limited thereto.

Since the interlayer insulating layer 146 is disposed between the first capacitor electrodes 116a to 116e and the second capacitor electrodes 118a to 118e, the interlayer insulating layer 146 and the plurality of first capacitor electrodes 116a to 116e and the second capacitor electrodes 118a to 118e interposed therebetween form a plurality of capacitors C1 to C5. In this case, the gate voltage may be applied to the first capacitor electrodes 116a to 116e, and the data voltage may be applied to the second capacitor electrodes 118a to 118e.

A first insulating layer 148 is formed on the interlayer insulating layer 146 on which the source electrode 114, the drain electrode 115, the second electrode 119, and the plurality of the second capacitor electrode 118a to 118e are disposed. The first insulating layer 148 may be formed of at least one of the organic insulating materials such as BCB (Benzo Cyclo Butene), acrylic resin, epoxy resin, phenolic resin, polyamide resin, or polyimide resin, but is not limited thereto.

A mini LED 180 is disposed on the first insulating layer 148. Although the mini LED 180 is formed on the upper surface of the first insulating layer 148 in the figure, the upper surface of the first insulating layer 148 may be removed to the predetermined thickness and the mini LED 180 may be disposed in the removed area. In this way, as the predetermined thickness of the first insulating layer 148 is removed, a step between the mini LED 180 and the first insulating layer 148 can be minimized and the increase of the thickness of the display apparatus 100 due to the mini LED 180 can be minimized.

The mini LED 180 may include a red mini LED 180, a green mini LED 180, and a blue mini LED 180, and these red, green, and blue mini LEDs 180 may be disposed in corresponding sub-pixels, respectively.

The mini LED 180 may be formed in a size of hundreds of μm. For example, the mini LED 180 may be formed by growing a plurality of thin films of inorganic materials such as Al, Ga, N, P, As In, etc. on a sapphire substrate or a silicon substrate, and then cutting and separating the sapphire substrate or the silicon substrate.

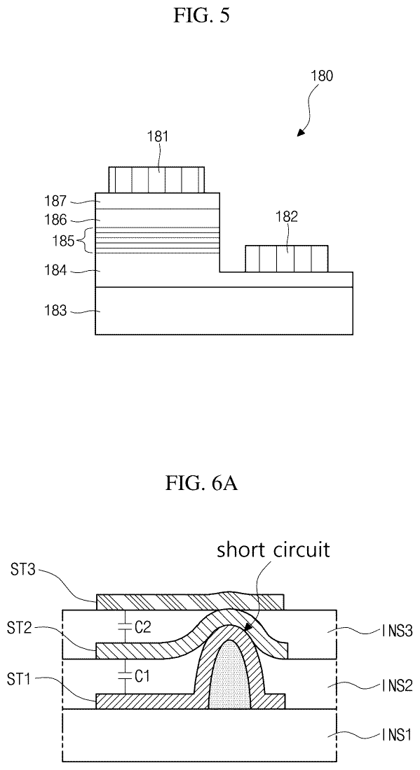

FIG. 5 is a view showing the structure of the mini LED 180 of FIG. 4. As shown in FIG. 5, the mini LED 180 includes a GaN layer 183 which is not doped, a n-type GaN layer 184 on the GaN layer 183, an active layer 185 having a Multi-Quantum-Well (MQW) structure on the n-type GaN layer 184, a p-type GaN layer 186 on the active layer 185, an ohmic contact layer 187 formed of a conductive transparent material on the p-type GaN layer 186, a p-type electrode 181 contacted with a portion of the ohmic contact layer 187, and a n-type electrode 182 contacted with a portion of the n-type GaN layer 184 exposed by etching a part of the active layer 185, the p-type GaN layer 186, and the ohmic contact layer 187.

The n-type GaN layer 184 is to supply electrons to the active layer 185 and may be formed by doping a GaN semiconductor layer with an n-type impurity such as Si.

The active layer 185 is a layer in which injected electrons and holes are combined to emit light. Although not shown in the figure, a plurality of barrier layers and well layers are alternately disposed in the multi-quantum-well structure of the active layer 185. The well layer is made of InGaN and the barrier layer is formed of GaN, but is not limited thereto.

The p-type GaN layer 186 injects holes into the active layer 185 and is formed by doping a GaN semiconductor layer with p-type impurities such as Mg, Zn, and Be.

The ohmic contact layer 187 is for ohmic contacting the p-type GaN layer 186 and the p-type electrode 181, and may be formed of the transparent metal oxide such as indium tin oxide (ITO), indium gallium zinc oxide (IGZO), or indium zinc oxide (IZO).

The p-type electrode 181 and the n-type electrode 182 may be formed of the single layer or the multi layers made of at least one of Ni, Au, Pt, Ti, Al, Cr, or the alloy thereof.

In the mini LED 180 of this structure, as the voltage is applied to the p-type electrode 181 and the n-type electrode 182, when the electrons and holes are injected from the n-type GaN layer 184 and the p-type GaN layer 186 to the active layer 185, respectively, excitons are generated in the active layer 185. As these excitons decay, light corresponding to an energy difference between the lowest unoccupied molecular orbital (LUMO) and the highest occupied molecular orbital (HOMO) of the light emitting layer is generated and emitted to the outside. At this time, the wavelength of light emitted from the mini LED 180 can be controlled by adjusting the thickness of the barrier layer of the multi-quantum-well structure of the active layer 185.

Although not shown in figure, the mini LED 180 is fabricated by forming the buffer layer on the substrate and growing the GaN thin film on the buffer layer. At this time, sapphire, silicon (Si), GaN, silicon carbide (SiC), gallium arsenide (GaAs), zinc oxide (ZnO), or the like may be used as the substrate.

When the substrate for growing the GaN thin film is made of the material other than the GaN, the buffer layer is to prevent quality degradation due to lattice mismatch that occurs when the n-type GaN layer 184, which is an epitaxial layer, is directly grown on the substrate. The buffer layer may be formed of AlN or GaN.

The n-type GaN layer 184 may be formed by growing the GaN film undoped with impurities and then doping an n-type impurity such as Si to the top surface of the undoped GaN film. Further, p-type GaN layer 186 may be formed by growing the GaN film undoped with impurities and then doping an p-type impurity such as Mg, Zn, or Be to the top surface of the undoped GaN film.

Referring back to FIG. 4, in the invention, the micro LED or the organic light emitting device may be used instead of the mini LED. The micro LED is an LED having a size of 100 μm or less, and the organic light emitting device includes a first electrode, a second electrode, and an organic light emitting layer therebetween.

A second insulating layer 150 is formed on the first insulating layer 148 on which the mini LED 180 is disposed to cover the mini LED 180. The second insulating layer 150 may be formed of at least one of the organic insulating materials such as BCB (BenzoCycloButene), acrylic resin, epoxy resin, phenolic resin, polyamide resin, or polyimide resin, but is not limited thereto. Further, the second insulating layer 150 may be formed of inorganic layer/organic layer or may be formed of inorganic layer/organic layer/inorganic layer.

A first contact hole CH1 and a second contact hole CH2 are respectively formed in the first insulating layer 148 and the second insulating layer 150 on the thin film transistor and the second electrode 119, so that the drain electrode 115 of the thin film transistor and the second electrode are exposed. Further, a third contact hole CH3 and a fourth contact hole CH4 are respectively formed in the second insulating layer 150 on the p-type electrode 181 and the n-type electrode 182 of the mini LED 180, so that the p-type electrode 181 and the n-type electrode 182 are exposed.

A first connection electrode 172 and a second connection electrode 174 made of the transparent metal oxide such as ITO, IGZO or IGO are formed on the second insulating layer 150. The first connection electrode 172 electrically connects the drain electrode 115 of the thin film transistor and the p-type electrode 181 of the mini LED 180 through the first contact hole CH1 and the third contact hole CH3. The second connection electrode 174 electrically connects the second electrode 119 and the n-type electrode 182 of the mini LED 180 through the second contact hole CH2 and the fourth contact hole CH4.

An encapsulation layer 190 is formed over the substrate 140 to encapsulate the mini LED 180. The encapsulation layer 190 may be formed of the single layer or the multi layers made of inorganic material such as SiNx and SiOxz. Further, the encapsulation layer 190 may be formed of a single layer or multiple layers made of polymer such as acryl resin), epoxy resin, SiOCz, epoxy, polyimide, polyethylene, and acrylate based material. In addition, the encapsulation layer 190 may be formed of a plurality of layers of the inorganic layer and the organic layer.

Meanwhile, in the figure, each of the plurality of capacitors C1 to C5 includes the first capacitor electrodes 116a to 116e on the gate insulating layer 144, the interlayer insulating layer 146, and the second capacitor electrodes 118a to 118e on the interlayer insulating layer 146, but the invention is not limited to this structure.

For example, each of the capacitors C1 to C5 of the invention may include the first capacitor electrodes 116a to 116e on the substrate 140, the buffer layer 142, the gate insulating layer 144, the interlayer insulating layer 146, and the second capacitor electrode 118a to 118e, and may include the first capacitor electrodes 116a to 116e, the interlayer insulating layer 146, the first insulating layer 148, and the second capacitor electrodes 118a to 118e.

Accordingly, the capacitors C1 to C5 of the invention may be designed in various ways according to the structure of the display apparatus 100, for example, the structure of the thin film transistor, the size of the set storage capacitance, and the like.

As described above, in the display apparatus 100 according to the invention, since the plurality of capacitors C1 to C5 are connected and disposed in parallel on the same plane, the following effects can be obtained.

In the invention, when the storage capacitor unit is defective due to a foreign material, it is possible to prevent the entire storage capacitor unit from being defective by limiting the defective region to a partial region.

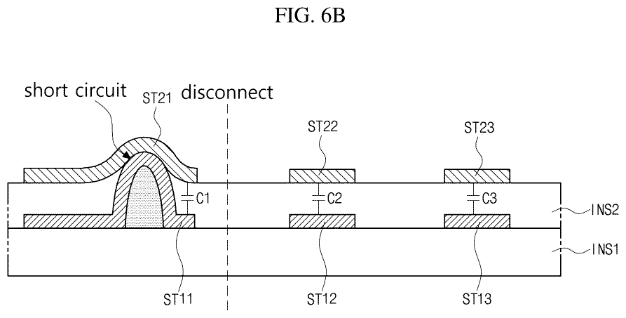

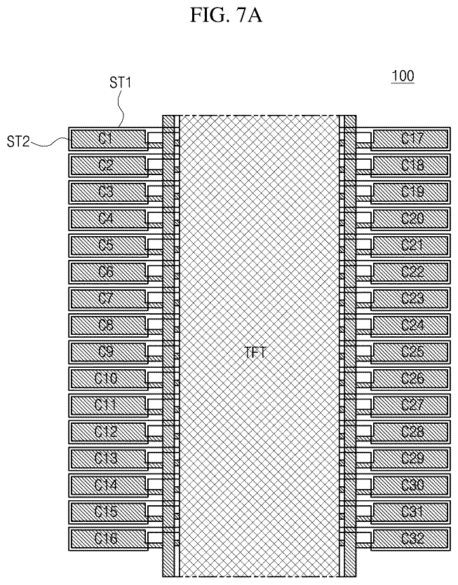

FIG. 6A is the view showing that the plurality of capacitors C1 to C5 are formed in the vertical structure, and FIG. 6B is the view showing the structure of the invention in which the plurality of capacitors C1 to C5 are formed in a horizontal structure.

As shown in FIG. 6A, in the vertical structure, the capacitor electrodes ST1, ST2, and ST3 are respectively disposed over the plurality of insulating layers INS1, INS2, and INS3, which are vertically deposited, to form a plurality of capacitors C1 and C2. In this structure, when the foreign substance is introduced, all of the plurality of capacitor electrodes ST1, ST2, and ST3 above the foreign substance are short-circuited, and thus all capacitors C1 and C2 are defective.

However, as shown in FIG. 6B, when the plurality of capacitors C1, C2, and C3 are horizontally divided and disposed, when the foreign substance is introduced in one area, only the electrodes ST11 and ST21 of the corresponding area are short-circuited, and the remaining electrodes ST12 and ST22, ST13 and ST23 are not short-circuited. Therefore, not all of the capacitors are defective, but only a portion of the capacitors are defective.

Further, in the invention, since the capacitor in the defective area is removed, the storage capacitor unit can be repaired.

That is, as shown in FIG. 6B, in the invention, since the defective regions ST11 and ST21 are disconnected from other regions, the storage capacitance can be stored by the storage capacitor unit which includes the second capacitor C2 and the third capacitor C3 but excluding the first capacitor C1.

When the defective area is disconnected, both connections of the lower electrode ST11 and the upper electrode ST21 may be disconnected, or only one connection of the lower electrode ST11 and the upper electrode ST21 may be disconnected.

In the invention, since the plurality of capacitors are divided and arranged on the same plane, sufficient storage capacity can be obtained.

When the capacitor has a vertical structure, since the number of layers of the display apparatus is limited, the number of capacitor electrodes is also limited. Therefore, in the display apparatus having the vertical capacitor structure, it is difficult to design the storage capacitance to have sufficient capacity. On the other hand, in the display apparatus 100 according to the invention, since the capacitors are divided and arranged horizontally on the same plane, sufficient storage capacity can be obtained.

In particular, in the invention, the storage capacity can be further increased by arranging the plurality of capacitors in various shapes on the plane. This will be explained below.

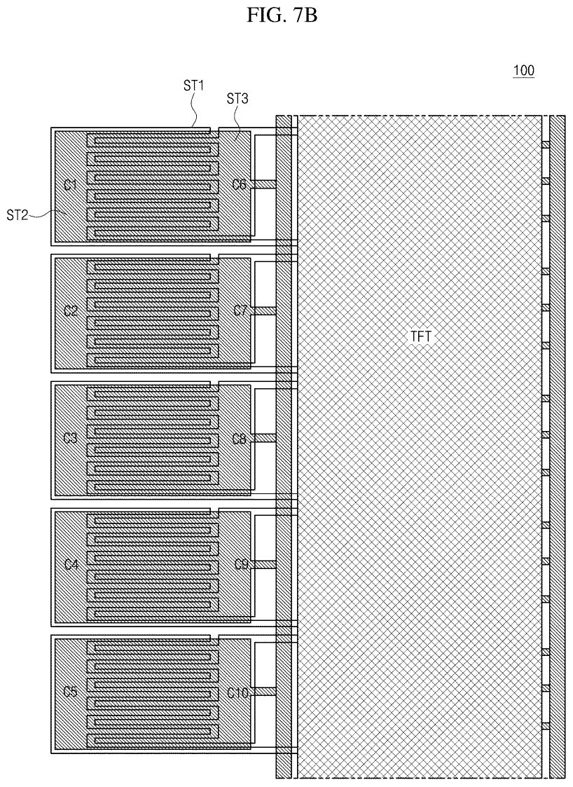

FIGS. 7A and 7B are views showing another structure of the display apparatus 100 according to the invention.

As shown in FIG. 7A, in the display apparatus 100 of this structure, the plurality of capacitors C1 to C32 are disposed in both sides of the TFT region in which thin film transistors are disposed. In this way, since the plurality of capacitors C1 to C32 are disposed in both sides of the TFT area of the sub-pixel instead of in one side, a large number of capacitors can be disposed, and as a result, sufficient storage capacity can be obtained.

Further, since the large number of capacitors C1-C32 are disposed on both sides of the TFT area, the size occupied by one capacitor is relatively small (i.e., the storage capacity of one capacitor is relatively small). Therefore, when the capacitor in the specific region is disconnected due to the defect in the specific region, the decrease of storage capacity due to the removed capacitor can be minimized, so that the repaired capacitor can have sufficient storage capacity.

As shown in FIG. 7B, in the display apparatus 100 of this structure, the plurality of capacitors C1 to C10 may be disposed in one side of the TFT area. Each of the plurality of capacitors C1 to C10 includes one lower electrode ST1, two first and second upper electrodes ST2 and ST3, and the insulating layer (not shown) therebetween. Both the first and second upper electrodes ST2 and ST3 overlap the lower electrode ST1 with the insulating layer interposed therebetween. Further, in the display apparatus 100 of this structure, the capacitor may include two lower electrodes, one upper electrode, and the insulating layer therebetween.

The lower electrode ST1 is formed in a rectangular shape, and the first upper electrode ST2 and the second upper electrode ST3 are disposed separately from each other in the left and right sides of the upper part of the lower electrode ST1. A finger portion is formed in the left side of the first upper electrode ST2 and the finger portion is also formed in the right side of the second upper electrode ST3. The finger portions of the first upper electrode ST2 and the second upper electrode ST3 facing each other are interlocked with each other.

In the display apparatus 100 having this structure, two capacitors C1 and C2 can be formed in the specific area by overlapping one lower electrode ST1 and two separated upper electrodes ST2 and ST3. Further, the overlapping area between each of the upper electrodes ST2 and ST3 and the lower electrode ST1 is maximized by forming the finger portions in the upper electrodes ST2 and ST3, so that the storage capacitance can be maximized. Therefore, the plurality of capacitors C1 to C10 having the maximum storage capacitance can be separated and disposed on a plane.

The above description and the accompanying drawings are merely illustrative of the technical spirit of the present invention, and those of ordinary skill in the art to which the present invention pertains can combine configurations within a range that does not depart from the essential characteristics of the present invention, various modifications or variations such as separation, substitution and alteration will be possible. Therefore, the embodiments disclosed in the present invention are not intended to limit the technical spirit of the present invention, but to explain, and the scope of the technical spirit of the present invention is not limited by these embodiments.

What is claimed is:

1. A display apparatus comprising:
a substrate including a plurality of sub-pixels;
a thin film transistor and a light emitting element disposed in each of the sub-pixels over the substrate; and
a plurality of capacitors disposed in parallel on a same plane in the sub-pixel.

2. The display apparatus of claim 1, wherein the thin film transistor includes;
a semiconductor layer on the substrate;
a gate insulating layer on the semiconductor layer;
a gate electrode on the gate insulating layer;
an interlayer insulating layer on the gate electrode; and
a source electrode and a drain electrode on the interlayer insulating layer.

3. The display apparatus of claim 2, wherein each of the plurality of capacitor includes:
a first capacitor electrode and a second capacitor electrode; and
an insulating layer between the first capacitor electrode and the second capacitor electrode.

4. The display apparatus of claim 2, wherein each of the plurality of capacitor includes:
a first capacitor electrode on the gate insulating layer;
the interlayer insulting layer; and
a second capacitor electrode on the interlayer insulating layer, the first capacitor electrode being overlapped with the second capacitor electrode with the interlayer insulating layer therebetween.

5. The display apparatus of claim 4, wherein the first capacitor electrode is formed of a same material as the gate electrode and the second capacitor electrode is formed of a same material as the drain electrode.

6. The display apparatus of claim 5, wherein the first capacitor electrode of the plurality of capacitors is connected to a first signal line connected to the gate electrode and the second capacitor electrode of the plurality of capacitors is connected to a second signal line connected to the source electrode.

7. The display apparatus of claim 6, wherein at least one of a connection of the first capacitor electrode and the first signal line and a connection of the second capacitor electrode and the second signal line is disconnected in a defective capacitor of the plurality of capacitors.

8. The display apparatus of claim 4, wherein the plurality of capacitors are disposed in one side of a region in which the thin film transistor is formed in the sub-pixel.

9. The display apparatus of claim 8, wherein two capacitors are formed by overlapping one first capacitor electrode and two second capacitor electrodes, and a finger portion is formed in each of the two second capacitor electrodes to interlock with each other.

10. The display apparatus of claim 4, wherein the plurality of capacitors are disposed in both sides of the portion in which the thin film transistor is formed in the sub-pixel.

11. The display apparatus of claim 1, wherein the display device is any one of a mini LED display device, a micro LED display device, and an organic light emitting device.

12. A display apparatus including a plurality of sub-pixels, at least one of the sub-pixels comprising:
a thin film transistor and a light emitting element connected in series to the thin film transistor; and
a plurality of capacitors electrically connected to one another in parallel,
wherein at least one of the capacitors is electrically disconnected from a first signal line connected to a gate electrode of the thin film transistor or is electrically disconnected from a second signal line connected to a source electrode of the thin film transistor, and
wherein remaining one of the capacitors are electrically connected to both the first signal line connected to the gate electrode of the thin film transistor and to the second signal line connected to the source electrode of the thin film transistor.

13. The display apparatus of claim 12, wherein the capacitors are disposed in parallel on a same plane in the at least one of the sub-pixels.

14. The display apparatus of claim 12, wherein the at least one of the capacitors is defective.

15. The display apparatus of claim 12, wherein the plurality of capacitors are disposed in one side of a region in which the thin film transistor is formed in the at least one of the sub-pixels.

16. The display apparatus of claim 12, wherein two capacitors of the plurality of capacitors are formed by overlapping one first capacitor electrode and two second capacitor electrodes, and a finger portion is formed in each of the two second capacitor electrodes to interlock with each other.

17. The display apparatus of claim 12, wherein the plurality of capacitors are disposed in both sides of a region in which the thin film transistor is formed in the at least one of the sub-pixels.
